(19) United States
(12) Patent Application Publication
(10) Pub. No.: US 2021/0129711 A1
(43) Pub. Date: May 6, 2021

(54) METHOD OF ANTI-COLLISION CONTROL OF MOVEMENTS OF A SEAT IN A VEHICLE

(71) Applicant: FAURECIA Sièges d'Automobile, Nanterre (FR)

(72) Inventors: Thierry MATHA, SAINT ARNOULT EN YVELINES (FR); Farouk BOUZID, BRETIGNY SUR ORGE (FR)

(21) Appl. No.: 17/079,988

(22) Filed: Oct. 26, 2020

(30) Foreign Application Priority Data
Oct. 30, 2019 (FR) 1912184

(51) Int. Cl. B60N 2/12; B60N 2/00; B60N 2/16; B60R 21/015

(52) U.S. Cl. CPC B60N 2/12; B60R 21/01554; B60N 2/16; B60N 2/002

(57) ABSTRACT

The present disclosure relates to a control method for controlling the movement of a seat, called the selected seat, for a motor vehicle equipped with a plurality of seats, comprising: a step of modeling a seat volume associated with each seat of the plurality of seats of the vehicle; an overlap determination step for determining the overlap, called the interference, during which it is determined whether there is at least partial overlap between the seat volume associated with the selected seat, called the selected volume, and the seat volume associated with each of the other seats of the plurality of seats of the vehicle, if the movement is performed; and a decision step, during which the movement is at least partially prohibited or allowed on the basis of the determination step.

### PRIORITY CLAIM

This application claims priority to French Patent Application No. FR 19 12184, filed Oct. 30, 2019, which is expressly incorporated by reference herein.

### BACKGROUND

The present disclosure relates a control method for controlling the movement of a seat arranged in a motor vehicle, and an associated system.

### SUMMARY

According to the present disclosure, a control method is described for controlling the movement of a seat, called the selected seat, for a motor vehicle equipped with a plurality of seats, the method comprising:

a step of modeling a seat volume associated with each seat of the plurality of seats of the vehicle;

an overlap determination step for determining the overlap, called the interference, during which it is determined whether there is at least partial overlap between the seat volume associated with the selected seat, called the selected volume, and the seat volume associated with each of the other seats of the plurality of seats of the vehicle if the movement is performed; and

a decision step, during which the movement is at least partially prohibited or allowed on the basis of the determination step.

Thus, when an overlap exists between the seat volume associated with the selected seat and the seat volume associated with each of the other seats, the movement of the seat is prohibited. As a result, collision is avoided between seats or between a seat and users.

In illustrative embodiments, the method comprises one or more of the following features, alone or in combination:

the overlap determination step further comprises the detection of a position associated with each of the seats of the plurality of seats;

the position associated with each of the seats of the plurality of seats is obtained based on the detection of a position associated with at least one motor arranged in each of the seats;

the position associated with each of the seats comprises at least one of:

a longitudinal position of at least one of the seat and at least one component element of the seat; and

a transverse position of at least one of the seat and the at least one component element of the seat; and

a vertical position of the at least one component element of the seat; and

an angular position of at least one of the seat and the at least one component element of the seat, in particular a tilt position of a backrest of the seat relative to a seating portion of the seat, the tilt position of the backrest being comprised in particular between a first position, called the folded-down position of the seat, and a second position, called the comfort position of the seat; and

a position of the seat linked to specific kinematics of the seat for ensuring a loading function of the vehicle;

the at least one motor controls the movement of the seat, the movement comprising at least one of:

a longitudinal translation of at least one of the seat and the at least one component element of the seat; and

a transverse translation of at least one of the seat and the at least one component element of the seat; and

a vertical translation of the at least one component element of the seat; and

a rotation of the seat about a vertical axis; and

a tilting of at least one of the seat and the at least one component element of the seat about an axis of rotation, in particular a tilting of the backrest of the seat relative to the seating portion of the seat, the tilting of the backrest being comprised in particular between the folded-down position of the seat and the comfort position of the seat; and

a movement of the seat linked to the specific kinematics of the seat for ensuring the loading function of the vehicle;

during the decision step, the movement is prohibited if, during the overlap determination step, it is determined that, in the event the movement is performed, overlap exists between the selected volume and the seat volume associated with each of the other seats of the plurality of seats of the vehicle;

the seat volume associated with each of the seats corresponds to the sum of an occupied volume obtained for each of the seats plus a tolerance factor;

the occupied volume corresponds to the sum of a total volume of the seat and a total volume of a possible occupant of the seat;

the movement may be performed by the entirety of the selected seat or by a portion thereof; and

the modeling step comprises a step of optically capturing the interior of the vehicle, performed by means of at least one optical element.

In illustrative embodiments, a system is described for implementing the control method as described above in all its configurations, the system comprising:

a plurality of seats,

means for modeling a seat volume associated with each of the seats of the plurality of seats of the vehicle, and

a calculation unit configured to determine whether an at least partial overlap exists between the seat volume associated with the selected seat, called the selected volume, and the seat volume associated with each of the other seats of the plurality of seats of the vehicle, in the event of the movement being performed, and to decide whether to at least partially prohibit or allow the movement.

In illustrative embodiments, a computer program is described comprising instructions for implementing all or part of the control method as described above in all its configurations when this program is executed by a processor.

In illustrative embodiments, a non-transitory computer-readable storage medium is described on which is stored the computer program as described above.

Additional features of the present disclosure will become apparent to those skilled in the art upon consideration of illustrative embodiments exemplifying the best mode of carrying out the disclosure as presently perceived.

### BRIEF DESCRIPTIONS OF THE DRAWINGS

The detailed description particularly refers to the accompanying figures in which:

FIG. 1 shows a schematic side view of a seat for a motor vehicle;

FIG. 2 shows a top view of a seating arrangement controlled by a method according to the present disclosure, in a first position;

FIG. 3 shows a top view of the seating arrangement of FIG. 2, in a second position;

FIG. 4 shows a top view of the seating arrangement of FIG. 2, in a third position; and

FIG. 5 shows a timing diagram of the method for controlling the movement of a seat according to the present disclosure.

### DETAILED DESCRIPTION

In the various figures, the same references designate identical or similar elements.

In the following description, the indications of spatial positioning such as top, bottom, upper, lower, horizontal, vertical, etc. are provided for clarity in the description, based on the usual position for using the seat, but are non-limiting. In particular, the orientations in relation to the front and rear of the seat are in relation to the usual position for using the seat.

Longitudinal direction is understood to mean any direction extending between the front and rear of the vehicle seat. Transverse direction is understood to mean any direction extending from one side of the vehicle seat to the other side of the vehicle seat. Preferably, the longitudinal and transverse directions are substantially horizontal. Vertical direction is understood to mean any direction perpendicular to the longitudinal and transverse directions.

The present disclosure is related to a control method 100 and an associated system.

The system comprises a plurality of seats 10.

Reference is now made to FIG. 1 to describe one of the seats 10, which a user wishes to move under the control of the method 100, and which is hereinafter referred to as the selected seat.

FIG. 1 schematically represents a side view of the seat 10 for a motor vehicle 1. Conventionally, such a seat 10 comprises a seating portion 12, a backrest 14, and a headrest 16. Advantageously, the seat 10 may include other component elements such as armrests, not shown.

The seating portion 12 is mounted on a seat support. The seat support may be fixed to the floor of the vehicle 1. Alternatively, the seat support may form part of the floor of the vehicle 1. Preferably, the seat support comprises at least one slider 18 comprising at least one rail 20 that is movable relative to at least one fixed section 22. The at least one movable rail 20 enables translational movement of the seat 10 in a direction parallel to the direction in which the at least one slider 18 extends.

For example, the seat support may comprise at least one first and at least one second slider 18. The at least one first slider 18 may extend in a longitudinal direction X, enabling the seat 10 to be moved in translation along the longitudinal direction X. The at least one second slider 18 may extend in a transverse direction Y, enabling the seat to be moved in translation along the transverse direction Y.

Advantageously, the seat 10 may be mounted on a pivot (not shown) enabling the seat 10 to be rotated in a first direction S1 and/or in a second direction S2 about a vertical axis Z. The vertical axis Z is preferably substantially perpendicular to the longitudinal direction X and to the transverse direction Y.

Mechanical connection means may be provided for interconnecting the various component elements of the seat 10. In particular, the mechanical connection means may interconnect the seating portion 12 and the backrest 14 on the one hand, and/or the backrest 14 and the headrest 16 on the other hand.

For example, the seating portion 12 and the backrest 14 may be interconnected by means of a pivot connection making it possible to adjust an angular position, or tilt position, of the backrest 14 relative to the seating portion 12 according to the preferences of a user of the seat 10. The seat 10 can thus be in a folded-down position where the backrest 14 is substantially parallel to the seating portion 12. Advantageously, in the folded-down position the seat can be used as a loading platform, thus enlarging the storage volume of the vehicle 1. Similarly, the seat 10 can be in a comfort position suitable for receiving an occupant. In the comfort position, the backrest 14 and the seating portion 12 form an angle that is preferably between 90° and 180°, more preferably between 110° and 150°.

Specific kinematics of the seat 10 further enable the seat 10 to adopt a position which increases the space available in the passenger compartment of the vehicle 1, in particular for storing luggage. Thus the seat 10 can adopt a position suitable for ensuring a loading function of the vehicle.

The backrest 14 and the headrest 16 may, for example, be interconnected by a slide-type connection which allows adjusting the height position of the headrest 16 according to the preferences of the user of the seat 10.

The mechanical connection means thus make it possible for a movement of the seat 10 to be performed only by certain component elements of the seat 10.

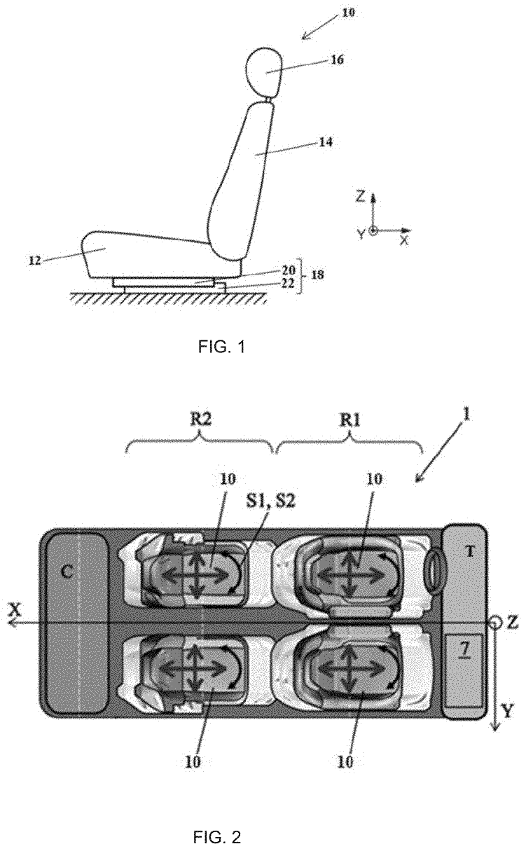

As illustrated in FIG. 2, the vehicle 1 has two rows R1, R2 arranged one behind the other along the longitudinal direction X. Each row has at least one seat 10. Preferably, at least two seats 10 are arranged per row R1, R2, as shown in FIG. 2.

The first row R1 is installed between the dashboard T of the vehicle 1 and the second row R2. The second row R2 is installed between the first row R1 and the trunk C of the vehicle 1.

At least one kinematic component (not illustrated) is associated with each seat 10. Preferably, at least one kinematic component is associated with each of the component elements of each seat 10. The at least one kinematic component controls the movement of the seat 10 and/or of the component elements of the seat 10. Thus, the seats 10 of each of the rows R1 and R2 can perform movements independently of each other, the movements being made by the entire seat 10 or by only certain component elements of the seat 10.

The movement of the seat and/or of the component elements of the seat 10 controlled by the at least one kinematic component may be:

a longitudinal translation of the seat 10 and/or of at least one component element of the seat 10; and/or

a transverse translation of the seat 10 and/or of the at least one component element of the seat 10; and/or

a vertical translation of the at least one component element of the seat 10; and/or

a rotation of the seat 10 about a vertical axis Z; and/or

a tilting of the seat 10 and/or of the at least one component element of the seat 10 about an axis of rotation, in particular a tilting of the backrest 14 of the seat 10 relative to the seating portion 12 of the seat 10, the tilting of the backrest 14 may be comprised in particular between the folded-down position of the seat 10 and the comfort position of the seat 10 for the occupant O; and/or

a movement of the seat 10 linked to the specific kinematics of the seat 10 for ensuring the loading function of the vehicle 1.

Longitudinal/transverse/vertical translation is understood to mean a movement of the seat and/or of at least one component element of the seat along the longitudinal X/transverse Y/vertical Z direction.

The at least one kinematic component may be, for example, an electric motor.

The system also comprises a positioning sensor associated with each of the motors (not shown), making it possible to determine the position of the at least one motor at any time. The detection of the position associated with the at least one motor also makes it possible to detect a position associated with each of the seats 10, and more specifically a position associated with each of the component elements of each seat 10 that is provided with the at least one motor.

For example, the position associated with each of the seats 10 comprises:

a longitudinal position of the seat 10 and/or of at least one component element of the seat 10; and/or

a transverse position of the seat 10 and/or of the at least one component element of the seat 10; and/or

a vertical position of the at least one component element of the seat 10; and/or

an angular position of the seat 10 and/or of the at least one component element of the seat 10, in particular an angular position of a backrest 14 of the seat 10 relative to a seating portion 12 of the seat 10, the angular position of the backrest 14 may be comprised in particular between a folded-down position of the seat 10 and a comfort position of the seat 10; and/or

a position of the seat 10 linked to specific kinematics of the seat 10 for ensuring a loading function of the vehicle 1.

Longitudinal/transverse/vertical position is understood to mean a position of the seat and/or of at least one component element of the seat along the longitudinal X/transverse Y/vertical Z direction.

The movements of the seats 10 are performed at the request of the user. At least one human-machine interaction means is provided in the vehicle 1 in order for the user to control the implementation of the movements. The at least one human-machine interaction means is, for example, placed on the dashboard T, the seats 10, and/or the doors of the vehicle 1.

The at least one human-machine interaction means is in the form of a physical button, but it may also be in the form of a virtual button. Advantageously, one human-machine interaction means exists per kinematic component associated with each seat 10.

A control unit 7 is configured to control the movement of the seats 10 within the vehicle 1. The control unit 7 is for example installed in a front portion of the vehicle 1 or under each seat 10, but any another position may be considered.

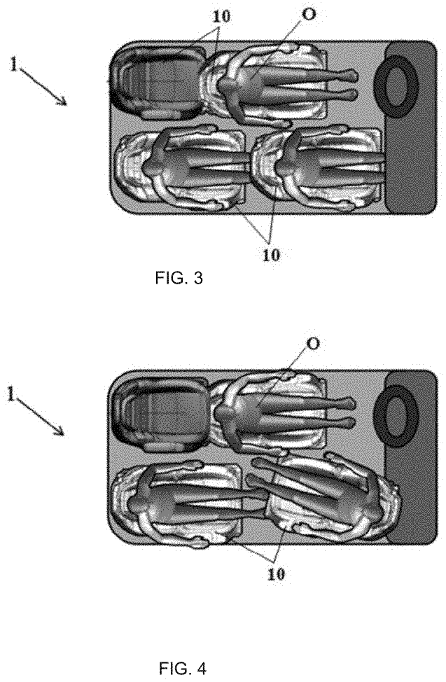

The mutual independence of the movements of the seats 10 could result in collisions inside the vehicle 1. For example, collisions could take place between several seats 10, as shown in FIG. 3, and/or between several occupants O of the seats 10, as shown in FIG. 4. Collisions could also take place between a seat 10 and an occupant O of another seat 10. The occupant O may be a person, an animal, an object, etc.

Preferably, the system also comprises means for modeling a seat volume associated with each of the seats 10 of the plurality of seats of the vehicle, and a calculation unit.

The seat volume corresponds to the sum of an occupied volume obtained for each seat, and optionally a tolerance factor calculated for each seat.

The volume occupied by each seat 10 corresponds to the sum of the total volume of the seat 10 in an unoccupied state, and where applicable a total volume of the occupant O of the seat 10.

The tolerance factor corresponds to a volume which is preferably greater than or equal to 0.5% of the volume occupied by the seat 10 and/or less than or equal to 15% of the volume occupied by the seat 10.

The means for modeling the seat volume comprise at least one device for analyzing the arrangement of the seats 10 and their occupants O. The analysis device comprises at least one optical element preferably placed in the front portion of the vehicle 1, for example in the interior rear-view mirror or the dashboard T. Other locations of the at least one optical element are conceivable, however.

The optical element may be, for example, a camera or a laser. The camera may be, for example, an infrared camera or a visible-light camera.

The calculation unit is configured to determine whether there is an at least partial overlap between the volume of the selected seat, called the selected volume, and the seat volume associated with each of the other seats of the plurality of seats 10 of the vehicle 1 if the movement of the selected seat ordered by the user is performed.

The calculation unit is also configured to decide whether to at least partially prohibit or allow the movement of the selected seat.

The calculation unit may further be configured to calculate a maximum distance the selected seat can move at the request of the user without resulting in collisions within the vehicle.

The method 100 for controlling the movement of the seats 10 is now described.

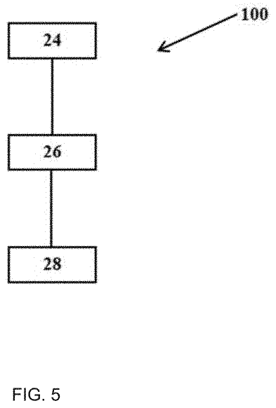

The method 100 is implemented each time the user of the seat 10 actuates the at least one human-machine interaction means in order to control the desired movement of the selected seat. As illustrated in FIG. 5, the method 100 comprises a modeling step 24, an overlap determination step 26, and a decision step 28.

The modeling step 24 comprises an optical capture step, for example by scanning, implemented by the at least one optical element already described.

In particular, the actuation of the at least one human-machine interaction means causes activation of the at least one optical element.

When the optical element is a camera, an image is captured of the interior of the vehicle at the moment of actuation of the human-machine interaction means.

Image processing analysis is then applied to the captured image in order to model the occupied volumes of the seats 10.

The modeling step 24 also comprises a step of determining the volumes of the seats 10, during which the tolerance factor is optionally added to the occupied volume(s).

Once the seat volume associated with each seat of the plurality of seats of the vehicle 1 is modeled, the step 26 of determining the overlap, also called the interference, is performed.

During the overlap determination step 26, the position associated with each of the seats 10 is detected via the positioning sensors associated with each of the motors.

Once the position associated with each seat 10 is obtained, it is determined whether the movement ordered by the user for the selected seat can cause a collision within the vehicle 1.

To do so, during the overlap determination step 26, it is evaluated whether performing the movement ordered by the user would cause an overlap between the selected volume and the seat volume associated with each of the other seats of the plurality of seats of the vehicle 1.

The overlap between the selected volume and the seat volume associated with each of the other seats may be total or partial.

During the overlap determination step 26, the maximum distance the selected seat can move without overlap may also be calculated.

Depending on the result of the overlap determination step 26, the ordered movement of the selected seat is allowed or prohibited in the decision step 28.

When the overlap determination step 26 determines that overlap exists, the decision step 28 prohibits the movement ordered by the user.

In the decision step 28, it is also possible that the ordered movement is partially prohibited. For example, if the user wants to move the selected seat by a distance greater than the maximum distance calculated in the determination step, movement of the seat will be prohibited once the selected seat has been moved by a distance equal to the maximum distance.

The present disclosure also relates to a computer program comprising instructions for implementing all or part of the method 100 when this program is executed by a processor. Preferably, the computer program is stored on a non-transitory computer-readable storage medium.

With the present disclosure, the number of collisions involving the seats 10 and/or the occupants O inside the vehicle 1 is partially or totally restricted.

The present disclosure is not limited to the example described above with reference to the figures. This disclosure also encompasses all variants and combinations conceivable to a person skilled in the art within the scope of the protection sought.

In the automotive field in particular, a comparative seat may be configured to be movable within a vehicle in order to adjust its position to the preferences of a user. In one example, the entirety of such a comparative seat may be moved, or only some of its parts.

Generally, a motor vehicle has a plurality of seats, the position of each seat being adjustable independently of the position of the other seats. Each user of the vehicle thus can travel with a desired level of comfort.

However, such an arrangement has the disadvantage of possibly causing collisions between seats, or between a seat and the user of another seat for example. This could cause damage to the seats and injury to the users.

This issue is of increasing importance with the growth of autonomous vehicles, in which the passengers and the driver are expected to move their seats more often. The present disclosure aims to improve the situation.

To this end, a control method is described for controlling the movement of a seat, called the selected seat, for a motor vehicle equipped with a plurality of seats, the method comprising:

a step of modeling a seat volume associated with each seat of the plurality of seats of the vehicle;

an overlap determination step for determining the overlap, called the interference, during which it is determined whether there is at least partial overlap between the seat volume associated with the selected seat, called the selected volume, and the seat volume associated with each of the other seats of the plurality of seats of the vehicle if the movement is performed; and

a decision step, during which the movement is at least partially prohibited or allowed on the basis of the determination step.

Thus, when an overlap exists between the seat volume associated with the selected seat and the seat volume associated with each of the other seats, the movement of the seat is prohibited. As a result, collision is avoided between seats or between a seat and users.

In one example, the method comprises one or more of the following features, alone or in combination:

the overlap determination step further comprises the detection of a position associated with each of the seats of the plurality of seats;

the position associated with each of the seats of the plurality of seats is obtained based on the detection of a position associated with at least one motor arranged in each of the seats;

the position associated with each of the seats comprises at least one of:

a longitudinal position of at least one of the seat and at least one component element of the seat; and

a transverse position of at least one of the seat and the at least one component element of the seat; and

a vertical position of the at least one component element of the seat; and

an angular position of at least one of the seat and the at least one component element of the seat, in particular a tilt position of a backrest of the seat relative to a seating portion of the seat, the tilt position of the backrest being comprised in particular between a first position, called the folded-down position of the seat, and a second position, called the comfort position of the seat; and

a position of the seat linked to specific kinematics of the seat for ensuring a loading function of the vehicle;

the at least one motor controls the movement of the seat, the movement comprising at least one of:

a longitudinal translation of at least one of the seat and the at least one component element of the seat; and

a transverse translation of at least one of the seat and the at least one component element of the seat; and

a vertical translation of the at least one component element of the seat; and

a rotation of the seat about a vertical axis; and

a tilting of at least one of the seat and the at least one component element of the seat about an axis of rotation, in particular a tilting of the backrest of the seat relative to the seating portion of the seat, the tilting of the backrest being comprised in particular between the folded-down position of the seat and the comfort position of the seat; and

a movement of the seat linked to the specific kinematics of the seat for ensuring the loading function of the vehicle;

during the decision step, the movement is prohibited if, during the overlap determination step, it is determined that, in the event the movement is performed, overlap exists between the selected volume and the seat volume associated with each of the other seats of the plurality of seats of the vehicle;

the seat volume associated with each of the seats corresponds to the sum of an occupied volume obtained for each of the seats plus a tolerance factor;

the occupied volume corresponds to the sum of a total volume of the seat and a total volume of a possible occupant of the seat;

the movement may be performed by the entirety of the selected seat or by a portion thereof; and

the modeling step comprises a step of optically capturing the interior of the vehicle, performed by means of at least one optical element.

According to another aspect of the present disclosure, a system is described for implementing the control method as described above in all its configurations, the system comprising:

a plurality of seats,

means for modeling a seat volume associated with each of the seats of the plurality of seats of the vehicle, and

a calculation unit configured to determine whether an at least partial overlap exists between the seat volume associated with the selected seat, called the selected volume, and the seat volume associated with each of the other seats of the plurality of seats of the vehicle, in the event of the movement being performed, and to decide whether to at least partially prohibit or allow the movement.

According to yet another aspect of the present disclosure, a computer program is described comprising instructions for implementing all or part of the control method as described above in all its configurations when this program is executed by a processor.

According to yet another aspect of the present disclosure, a non-transitory computer-readable storage medium is described on which is stored the computer program as described above.

1. A control method for controlling the movement of a seat, called the selected seat, for a motor vehicle equipped with a plurality of seats, the method comprising:
a step of modeling a seat volume associated with each seat of the plurality of seats of the vehicle;
an overlap determination step for determining the overlap, called the interference, during which it is determined whether there is at least partial overlap between the seat volume associated with the selected seat, called the selected volume, and the seat volume associated with each of the other seats of the plurality of seats of the vehicle, if the movement is performed; and
a decision step, during which the movement is at least partially prohibited or allowed on the basis of the determination step.

2. The control method of claim 1, wherein the overlap determination step further comprises the detection of a position associated with each of the seats of the plurality of seats.

3. The control method of claim 2, wherein the position associated with each of the seats of the plurality of seats is obtained based on the detection of a position associated with at least one motor arranged in each of the seats.

4. The control method of claim 3, wherein the position associated with each of the seats comprises at least one of:
a longitudinal position of at least one of the seat and at least one component element of the seat; and
a transverse position of at least one of the seat and the at least one component element of the seat; and
a vertical position of the at least one component element of the seat; and
an angular position of at least one of the seat and the at least one component element of the seat, in particular a tilt position of a backrest of the seat relative to a seating portion of the seat, the tilt position of the backrest being comprised in particular between a first position, called the folded-down position of the seat, and a second position, called the comfort position of the seat; and
a position of the seat linked to specific kinematics of the seat for ensuring a loading function of the vehicle.

5. The control method of claim 4, wherein the at least one motor controls the movement of the seat, the movement comprising at least one of:
a longitudinal translation of at least one of the seats and the at least one component element of the seat; and
a transverse translation of at least one of the seats and the at least one component element of the seat; and
a vertical translation of the at least one component element of the seat; and
a rotation of the seat about a vertical axis; and
a tilting of at least one of the seat and the at least one component element of the seat about an axis of rotation, in particular a tilting of the backrest of the seat relative to the seating portion of the seat, the tilting of the backrest being comprised in particular between the folded-down position of the seat and the comfort position of the seat; and
a movement of the seat linked to the specific kinematics of the seat for ensuring the loading function of the vehicle.

6. The control method of claim 1, wherein the movement is prohibited during the decision step if, during the overlap determination step, it is determined that, in the event the movement is performed, overlap exists between the selected volume and the seat volume associated with each of the other seats of the plurality of seats of the vehicle.

7. The control method of claim 1, wherein the seat volume associated with each of the seats corresponds to the sum of an occupied volume obtained for each of the seats plus a tolerance factor.

8. The control method of claim 7, wherein the occupied volume corresponds to the sum of a total volume of the seat and a total volume of a possible occupant of the seat.

9. The control method of claim 1, wherein the movement may be performed by the entirety of the selected seat or by a portion thereof.

10. A system for implementing the control method according to claim 1, comprising:
a plurality of seats,
means for modeling a seat volume associated with each of the seats of the plurality of seats of the vehicle, and
a calculation unit configured to determine whether an at least partial overlap exists between the seat volume associated with the selected seat, called the selected volume, and the seat volume associated with each of the other seats of the plurality of seats of the vehicle, in the event of the movement being performed, and to decide whether to at least partially prohibit or allow the movement.

11. A computer program comprising instructions for implementing all or part of the control method according to claim 1 when this program is executed by a processor.

12. A non-transitory computer-readable storage medium on which is stored the computer program according to claim 11.
